(19) United States
(12) Patent Application Publication
(10) Pub. No.: US 2024/0038948 A1
(43) Pub. Date: Feb. 1, 2024

(54) DISPLAY PANEL AND SPLICING SCREEN

(71) Applicant: WUHAN CHINA STAR OPTOELECTRONICS SEMICONDUCTOR DISPLAY TECHNOLOGY CO., LTD., Wuhan, Hubei (CN)

(72) Inventors: Likun Cheng, Wuhan, Hubei (CN); Liang Sun, Wuhan, Hubei (CN); He Jiang, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/622,850

(22) PCT Filed: Dec. 21, 2021
(86) PCT No.: PCT/CN2021/140019

§ 371 Date: Jun. 22, 2023

(30) Foreign Application Priority Data
Dec. 13, 2021 (CN) 202111523324.X

(51) Int. Cl. H01L 33/62; H01L 25/16; H01L 27/12

(52) U.S. Cl. CPC H01L 33/62; H01L 25/167; H01L 27/124

(57) ABSTRACT

A display panel and a splicing screen are provided. The display panel includes a first substrate and a second substrate. The pixel unit on the first substrate includes a light-emitting area and a vacant area. The light-emitting area is provided with a light-emitting diode chip and a pixel driving circuit. At least one conductive hole is provided in the vacant area. The second substrate is arranged on a side of the first substrate facing away from the pixel unit, and the pixel driving circuit is electrically connected to a bonding conductive layer included in the second substrate through the conductive hole, which can eliminate a lower frame of the first substrate and prevent crack extension.

### BACKGROUND OF INVENTION

### 1. Field of Invention

The present invention relates to a technical field of displays, and more particularly to a display panel and a splicing screen.

### 2. Related Art

Currently, screen aspect ratios of electronic product screens are getting larger and larger, and full screens have become a trend as people have been looking forward to. However, there are circuit designs, such as fan-out wiring and bonding terminals in bonding areas of current display panels. In order to reduce bottom frames, the bonding areas are usually bent to the back of display panels, resulting in bending marks and protection marks for side traces, making lower frames of the display panels still indispensable, and failing in achievement of full screens.

### SUMMARY OF INVENTION

An object of the embodiment of the present application is to provide a display panel and a splicing screen to solve a technical problem that current display panels cannot be structured without lower frames.

To achieve the above-mentioned object, the present application provides a technical solution as follows:
The present application provides a display panel, including a first substrate on which a plurality of pixel units are disposed, each of the pixel units comprising a light-emitting area and a vacant area, wherein a light-emitting diode (LED) chip and a pixel driving circuit for driving the LED chip to emit light are disposed in the light-emitting area, the vacant area is an area where the pixel driving circuit and the LED chip are not provided, at least a conductive hole is located in the vacant area of at least some of the pixel units, and the conductive hole is filled with a conductive adhesive; and a second substrate disposed on a side of the first substrate facing away from the pixel units, wherein an orthographic projection of the second substrate on the first substrate is located in the first substrate, a bonding conductive layer is disposed on the second substrate, and the pixel driving circuit is electrically connected to the bonding conductive layer through the conductive hole.

According to the display panel provided by this application, the first substrate further comprises a plurality of contact terminals disposed corresponding to the conductive holes, and one end of each of the contact terminals is electrically connected to the pixel driving circuit; and the bonding conductive layer comprises a plurality of bonding terminals and a plurality of bonding traces, one end of each of the bonding traces is electrically connected to a corresponding one of the bonding terminals, and the other end of the bonding trace is electrically connected to the other end of the contact terminal through the conductive hole.

According to the display panel provided by this application, the bonding traces comprise a plurality of fan-out traces, the pixel driving circuit comprises a source and drain metal layer, and the source and drain metal layer comprises a plurality of data lines, wherein each of the data lines is electrically connected to a corresponding one of the fan-out traces through the conductive hole.

According to the display panel provided by this application, the bonding traces comprise a plurality of clock signal lines, the first substrate further comprises a gate driving circuit, and the gate driving circuit is electrically connected to the clock signal lines through the conductive holes.

According to the display panel provided by this application, the gate driving circuit comprises a plurality of cascaded circuit units, and each of the circuit units is located in the vacant area.

According to the display panel provided by this application, the first substrate comprises a first side and a second side that are oppositely disposed, and all the conductive holes are arranged close to the first side.

The present application provides a display panel, including a first substrate on which a plurality of pixel units are disposed, each of the pixel units comprising a light-emitting area and a vacant area, wherein a light-emitting diode (LED) chip and a pixel driving circuit for driving the LED chip to emit light are disposed in the light-emitting area, the vacant area is an area where the pixel driving circuit and the LED chip are not provided, and at least a conductive hole is located in the vacant area of at least some of the pixel units; and a second substrate disposed on a side of the first substrate facing away from the pixel units. A bonding conductive layer is disposed on the second substrate, and the pixel driving circuit is electrically connected to the bonding conductive layer through the conductive hole.

According to the display panel provided by this application, the first substrate further comprises a plurality of contact terminals disposed corresponding to the conductive holes, and one end of each of the contact terminals is electrically connected to the pixel driving circuit; and the bonding conductive layer comprises a plurality of bonding terminals and a plurality of bonding traces, one end of each of the bonding traces is electrically connected to a corresponding one of the bonding terminals, and the other end of the bonding trace is electrically connected to the other end of the contact terminal through the conductive hole.

According to the display panel provided by this application, the bonding traces comprise a plurality of fan-out traces, the pixel driving circuit comprises a source and drain metal layer, and the source and drain metal layer comprises a plurality of data lines, wherein each of the data lines is electrically connected to a corresponding one of the fan-out traces through the conductive hole.

According to the display panel provided by this application, the bonding traces comprise a plurality of clock signal lines, the first substrate further comprises a gate driving circuit, and the gate driving circuit is electrically connected to the clock signal lines through the conductive holes.

According to the display panel provided by this application, the gate driving circuit comprises a plurality of cascaded circuit units, and each of the circuit units is located in the vacant area.

According to the display panel provided by this application, the first substrate comprises a first side and a second side that are oppositely disposed, and all the conductive holes are arranged close to the first side.

According to the display panel provided by this application, the first substrate comprises a first side and a second side that are oppositely disposed, some of the conductive holes are located close to the first side, and some of the conductive holes are located close to the second side.

According to the display panel provided by this application, the second substrate comprises a first fan-out area and a second fan-out area, an orthographic projection of the first fan-out area on the first substrate is close to the first side, and an orthographic projection of the second fan-out area on the first substrate is close to the second side; and a driving chip is further provided on the second substrate, electrically connected to the bonding terminals, and disposed between the first fan-out area and the second fan-out area.

According to the display panel provided by this application, number of the conductive holes is greater than or equal to number of the bonding traces.

According to the display panel provided by this application, an orthographic projection of the second substrate on the first substrate is located in the first substrate.

According to the display panel provided by this application, the conductive hole is filled with a conductive adhesive.

According to the display panel provided by this application, the first substrate further comprises a first base and a first buffer layer, the first buffer layer disposed on a side of the first base away from the second substrate, and the pixel driving circuit arranged on a side of the first buffer layer away from the second substrate. The pixel driving circuit comprises a semiconductor layer disposed on the side of the first buffer layer away from the second substrate; a first gate insulating layer covering the semiconductor layer and the first buffer layer; a first gate layer disposed on the first gate insulating layer; a second gate insulating layer covering the first gate layer and the first gate insulating layer; a second gate layer disposed on the second gate insulating layer; n interlayer dielectric layer covering the second gate layer and the second gate insulating layer; and source and drain metal layer arranged on the interlayer dielectric layer. The conductive hole penetrates the interlayer dielectric layer, the first gate insulating layer, the second gate insulating layer, and the first buffer layer.

According to the display panel provided by this application, the second substrate further comprises a second base, wherein the bonding conductive layer is disposed on a side of the second base close to the first substrate; and a second buffer layer covering the second base and the bonding conductive layer, the conductive hole extends from the first substrate to the second substrate and penetrates the second buffer layer.

The present application provides a splicing screen, comprising a plurality of spliced display panels, wherein each of the display panel comprises a first substrate on which a plurality of pixel units are disposed, each of the pixel units comprising a light-emitting area and a vacant area, wherein a light-emitting diode (LED) chip and a pixel driving circuit for driving the LED chip to emit light are disposed in the light-emitting area, the vacant area is an area where the pixel driving circuit and the LED chip are not provided, and at least a conductive hole is located in the vacant area of at least some of the pixel units; and a second substrate disposed on a side of the first substrate facing away from the pixel units. A bonding conductive layer is disposed on the second substrate, and the pixel driving circuit is electrically connected to the bonding conductive layer through the conductive hole.

The present application has advantageous effects as follows: in the display panel and the splicing screen provided by the embodiments of the present application, based on the second substrate added to one side of the first substrate, the bonding conductive layer located on the lower frame of the first substrate as used in the prior art is transferred to the second substrate, and at least one conductive hole is located in the vacant area of the pixel unit of the first substrate, so that the pixel driving circuit disposed on the first substrate is electrically connected to the bonding conductive layer through the conductive hole, thereby achieving signal transmission across the substrates; since the first substrate does not need to leave space for arranging the bonding conductive layer, the lower frame of the first substrate can be completely eliminated, which is beneficial to achieve a full screen. In addition, the LED chip provided in the pixel unit has a self-encapsulation feature, which makes the area of the vacant area large enough to effectively prevent the formation of the conductive hole by mechanical processing from causing cracks to extend to the light-emitting area.

### BRIEF DESCRIPTION OF DRAWINGS

In order to better illustrate the technical solutions in the embodiments of the present application, the following will briefly introduce the accompanying drawings that need to be used in the description of the embodiments. Apparently, the accompanying drawings in the following description show merely some embodiments of the present invention, and a person skilled in the art may still derive other drawings from these accompanying drawings without creative efforts.

FIG. 1 is a schematic structural plan view of a display panel provided by an embodiment of the present application.

FIG. 2A is a schematic cross-sectional view of the display panel of FIG. 1.

FIG. 2B is a schematic structural plan view of a pixel unit of FIG. 2A.

FIG. 3 is a schematic structural plan view of another display panel provided by an embodiment of the present application.

FIG. 4 is a schematic structural plan of a splicing screen provided by an embodiment of the present application.

FIG. 5 is a schematic cross-sectional view of the splicing screen of FIG. 4.

### DESCRIPTION OF PREFERRED EMBODIMENTS

The technical solutions in the embodiments of the present application will be clearly and completely described below in conjunction with the drawings in the embodiments of the present application. Obviously, the described embodiments are only a part of the embodiments of the present application, rather than all the embodiments. Based on the embodiments in this application, all other embodiments obtained by those skilled in the art without creative work shall fall within the protection scope of this application. It should be understood that the specific embodiments described here are only used to illustrate the present application, and are not used to limit the present application. In this application, if no explanation is made to the contrary, the orientation words used, such as “upper” and “lower” usually refer to the upper and lower positions of the device in actual use or working state. Specifically, they refer to the direction of the drawings, and “inner” and “outer” refer to the outline of the device.

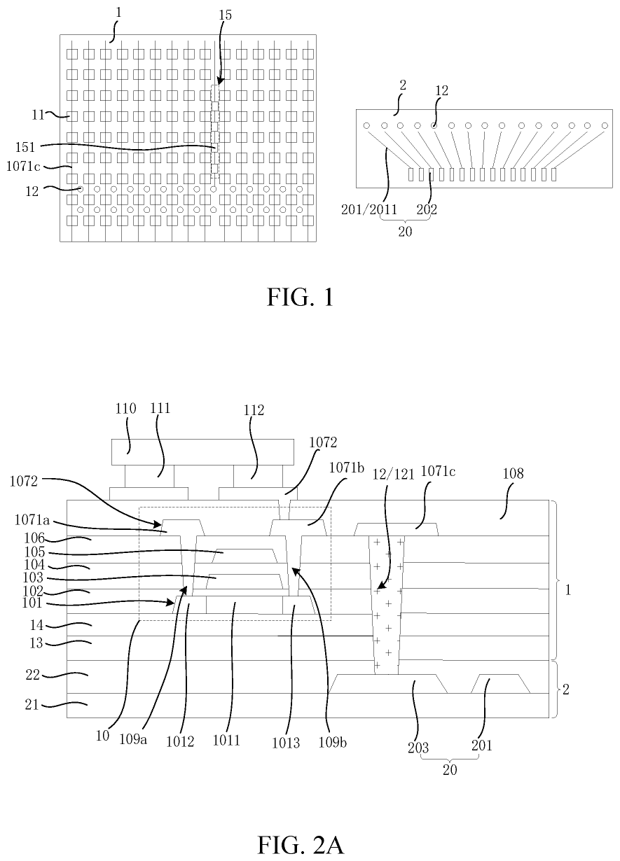

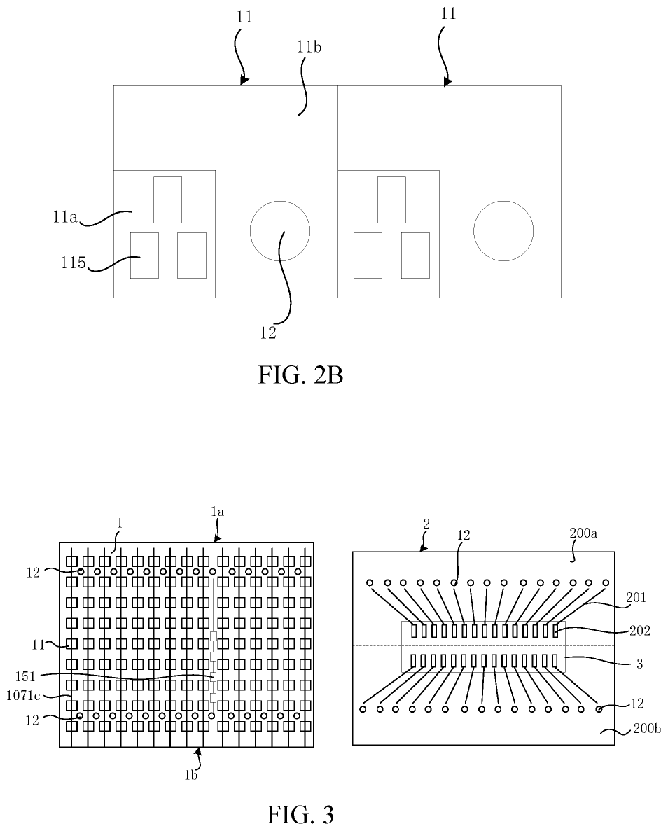

Please refer to FIG. 1, FIG. 2A, and FIG. 2B. FIG. 1 is a schematic structural plan view of a display panel provided by an embodiment of the present application. FIG. 2A is a schematic cross-sectional view of the display panel of FIG. 1. FIG. 2B is a schematic structural plan view of a pixel unit of FIG. 2A. An embodiment of the present application provides a display panel 100 that includes a first substrate 1 and a second substrate 2, and the second substrate 2 is disposed on one side of the first substrate 1.

A plurality of pixel units 11 are disposed on the first substrate 1. The pixel unit 11 includes a light-emitting diode (LED) chip 110 and a pixel driving circuit 10 for driving the LED chip 110 to emit light. Each of the pixel units 11 includes a light-emitting area 11a and a vacant area 11b, and the LED chip 110 and the pixel driving circuit 10 are located in the light-emitting area 11a. Specifically, the vacant area 11b is an area where the pixel driving circuit 10 and the LED chip 110 are not provided. At least a conductive hole 12 is located in the vacant area 11b of at least some of the pixel units 11; the second substrate 2 is disposed on a side of the first substrate 1 facing away from the pixel units 11. A bonding conductive layer 20 is disposed on the second substrate 2, and the pixel driving circuit 10 is electrically connected to the bonding conductive layer 20 through the conductive hole 12.

It can be understood that, in the embodiment of the present application, the second substrate 2 is added to one side of the first substrate 1. By transferring the bonding conductive layer 20 located on a lower frame of the first substrate 1 in the prior art to the second substrate 2, and providing at least one conductive hole 12 in the vacant area 11b of the pixel unit 11 of the first substrate 1, the pixel driving circuit 10 disposed on the first substrate 1 is electrically connected to the bonding conductive layer 20 through the conductive hole 12, thereby achieving signal transmission across the substrates; since the first substrate 1 does not need to leave space for arranging the bonding conductive layer 20, the lower frame of the first substrate 1 can be completely eliminated, which is beneficial to achieve a full screen.

Referring to FIG. 2B, each of the pixel units 11 includes the light-emitting area 11a and the vacant area 11b. The light-emitting area 11a is configured for arranging a light-emitting unit and the pixel driving circuit 10 for driving the light-emitting unit to emit light. The vacant area 11b is configured for placing the conductive hole 12 and setting functional units.

It should be noted that the display panel 100 may be a micro LED display panel or a mini LED display panel. In order to clearly explain the technical solution of the present application, the embodiment of the present application takes the display panel 100 as an example of a micro LED display panel for illustration.

In this embodiment, the LED chip 110 is a micro LED chip, which does not need to be packaged on a whole surface and is made of inorganic luminescent materials with stable physical and chemical properties, without the need for strict packaging, thus fundamentally solving the problem of packaging boundaries, thereby completely eliminating left and right borders of the display panel 100. In addition, compared to organic light-emitting diode units, the LED chip 110 has a smaller light-emitting area. For a single pixel unit 11, an area of the light-emitting area 11a is relatively small, so that an area of the vacant area 11b is larger. Therefore, sufficient space is provided for formation of the conductive hole 12, which can meet the demand of hole opening; Furthermore, the area of the vacant area 11b is large enough to effectively prevent the formation of the conductive hole 12 by mechanical processing from causing cracks to extend to the light-emitting area, thereby preventing affecting the normal light emission of the LED chip 110.

It should be noted that a center distance between two adjacent ones of the pixel units 11 should meet packaging requirements of organic light-emitting layers, so as to prevent an edge of a display area from being unable to show an “encapsulation edge”, so that the left and right borders of the display panel 100 can be completely eliminated.

Specifically, in order to meet the space required for the hole opening, the center distance between adjacent ones of the pixel units 11 may be 250 microns, 300 microns, 350 microns, etc., but the embodiment of the present application should not be limited thereto.

Specifically, a size of the conductive hole 12 may be 100 microns, 80 microns, etc., but the embodiment of the present application should not be limited thereto.

Optionally, only one conductive hole 12 may be provided in the empty area 11b of each pixel unit 11, or a plurality of conductive holes 12 may be provided.

Please continue to refer to FIG. 1 and FIG. 2A. The bonding conductive layer 20 includes a plurality of bonding traces 201 and a plurality of bonding terminals 202, and one end of each of the bonding traces 201 is electrically connected to a corresponding one of the bonding terminals 202. The first substrate further includes a plurality of contact terminals 203. The contact terminals 203 are arranged corresponding to the conductive holes 12. One end of each of the contact terminals 203 is electrically connected to the pixel driving circuit 10. The other end of the bonding trace 201 is electrically connected to the other end of the contact terminal 203 through the conductive hole 203, so that the bonding trace 201 is electrically connected to the pixel driving circuit 10 through the corresponding contact terminal 203. Compared with the bonding trace 201 directly contacting the pixel driving circuit 10 through the conductive hole 12, by using the fashion in the embodiment of the present application, the precise alignment of the first substrate 1 and the second substrate 2 can be realized, thereby preventing the misalignment of the signal caused by the alignment offset, which is beneficial to improve a display effect.

At least one driving chip 3 is further disposed on the second substrate, and a plurality of driving terminals (not shown) are provided on the driving chip. The driving terminals are electrically connected to the bonding terminals 202 in a one-to-one correspondence, so as to transmit signals in the driving chip to the pixel driving circuit 10 through the bonding traces 201. Thus, the pixel units 11 on the first substrate 1 are driven to achieve normal light-emitting display.

It is understood that, in the embodiment of the present application, the pixel driving circuit 10 on the first substrate 1 and the bonding trace 201 on the second substrate 2 are electrically connected through the formation of the conductive hole 12. Compared with the prior art where the bonding conductive layer 20 is disposed on the lower frame of the first substrate 1, in the embodiment of the present application, the first substrate 1 does not need to be provided with a bonding area for placing the bonding conductive layer and the driving chip 3, and it is not necessary to bend the bonding area to the side of the first substrate 1 facing away from the pixel unit 11, so that a width of a bending radius is saved, thereby completely eliminating the lower frame of the display panel 100; in addition, the use of the conductive hole 12 to achieve the connection mode of signal transmission across the substrates improves the stability of the electrical connection between the driving circuit and the bonding conductive layer 20, and prevents a situation that the bonding traces 201 are damaged or even broken due to the bending stress when the bonding traces 201 are bent.

Specifically, a size of the contact terminal 203 is larger than a size of the conductive hole 12. Optionally, in the embodiment of the present application, the size of the contact terminal 203 may be 200 microns.

Specifically, a material of the contact terminal 203 may be pure metal, metal alloy, semiconductor material, or other conductive materials. Optionally, in the embodiment of the present application, the contact terminal 203 may be formed by stacking multiple layers of metal. Correspondingly, in order to increase a trace space and reduce the size of the second substrate 2, the bonding traces 201 may also be formed by multi-layered metal stacking, and the bonding traces 201 and the contact terminals 203 on a same layer are electrically connected.

In one embodiment, the bonding traces 201 include a plurality of fan-out wires 2011. The pixel driving circuit 10 includes a source and drain metal layer 107. The source and drain metal layer 107 includes a plurality of data lines 1071c, and each of the data lines 1071c is electrically connected to a corresponding one of the fan-out traces 2011 through the conductive hole 12, thereby realizing the corresponding connection between the data line 1071c and the fan-out wire 2011.

In one embodiment, the bonding traces 201 include a plurality of clock signal lines, the first substrate 1 further includes a gate driving circuit and the gate driving circuit 15 is electrically connected to the clock signal lines through the conductive holes 12.

Further, please continue referring to FIG. 1 and FIG. 3. The gate driving circuit 15 includes a plurality of cascaded circuit units 151. The circuit units 151 are disposed in the vacant area 11b. Compared with the gate driving circuit 15 in the prior art, which is disposed on opposite sides of the first substrate 1, in the embodiment of the present application, the gate driving circuit 15 is arranged in the pixel unit 11, which eliminates the left and right borders of the display panel 100, so that a non-display area of the display panel 100 can be completely eliminated, and thus an entire area of the first substrate 1 is a display area, which is beneficial to achieve a full screen.

Further, an orthographic projection of the second substrate 2 on the first substrate 1 is completely located on the first substrate 1 to ensure that edges of the second substrate 2 do not exceed edges of the first substrate 1, thereby preventing the second substrate 2 from adversely affecting an overall size of the display panel 100. The present application does not have other restrictions on the size of the second substrate 2, and it only needs to meet requirements for accommodating the bonding conductive layer 20. Preferably, in order to save costs, the size of the second substrate 2 is equivalent to the size of the bonding area of the first substrate 1 in the prior art.

It should be noted that the bonding traces 201 may also be other traces other than the fan-out traces 2011 and the clock signal line stated in the embodiment of the present application. For example, the bonding traces 201 may be electrostatic protection circuit traces or subpixel deinterleaving circuit traces, etc. Correspondingly, the display panel 100 further includes an electrostatic protection circuit and a sub-pixel deinterleaving circuit. The electrostatic protection circuit trace is electrically connected to the electrostatic protection circuit, and the subpixel deinterleaving circuit trace is electrically connected to the subpixel deinterleaving circuit.

Further, similar to the gate driving circuit 15, since the electrostatic protection circuit and the subpixel deinterleaving circuit are small in size and can be divided into multiple circuit units, the electrostatic protection circuit and the subpixel deinterleaving circuit may be disposed in some of the pixel units 11 of the vacant area 11b. Likewise, the electrostatic protection trace is electrically connected to the electrostatic protection circuit through the corresponding conductive hole 12, and the subpixel deinterleaving circuit trace is electrically connected to the subpixel deinterleaving circuit through the corresponding conductive hole 12. Certainly, the electrostatic protection circuit and the subpixel deinterleaving circuit may also be disposed on the second substrate 2, and the embodiment of the present application is not limited thereto.

Specifically, number of the conductive holes 12 is greater than or equal to number of the bonding traces 201 to ensure that corresponding signals can be transmitted to each of the bonding traces 201 through the conductive holes 12, and then is transmitted to each of the pixel driving circuits 10.

Further, the conductive holes 12 are filled with a conductive adhesive 121 so that the pixel driving circuit 10 is connected to the bonding conductive layer 20 through the conductive adhesive 121. Specifically, when the bonding trace 201 is the fan-out trace 2011, the data line 1071c is electrically connected to the fan-out trace 2011 through the conductive adhesive 121; when the bonding trace 201 is the clock signal line, the gate driving circuit is electrically connected to the clock signal line through the conductive adhesive 121.

Optionally, the conductive adhesive 121 may be conductive silver paste.

In one embodiment, as shown in FIG. 1, the first substrate 1 includes a first side 1a and a second side 1b that are arranged oppositely. All the conductive holes 12 are arranged close to the first side 1a; in this fashion, an orthographic projection of the fan-out area of the second substrate 2 on the first substrate 1 is close to the first side 1a, and the driving chip 3 is disposed on one side of the fan-out area.

In one embodiment, as shown in FIG. 3, the first substrate 1 includes the first side 1a and the second side 1b that are arranged oppositely. Some of the conductive holes 12 are arranged close to the first side 1a, and some of the conductive holes 12 are arranged close to the second side 1b, that is, the plurality of the conductive holes 12 are arranged on opposite sides of the first substrate 1, and the bonding traces 201 do not need to be arranged on one side of the second substrate 2, which is beneficial for optimizing wiring. The second substrate 2 includes a first fan-out area 200a and a second fan-out area 200b. An orthographic projection of the first fan-out area 200a on the first substrate 1 is close to the first side 1a, and an orthographic projection of the second fan-out area 200b on the first substrate 1 is close to the second side 1b; the driving chip 3 is disposed between the first fan-out area 200a and the second fan-out area 200b.

Further, referring to FIG. 2A, the first substrate 1 further includes a first base 13 and a first buffer layer 14. The first buffer layer 14 is disposed on a side of the first base 13 away from the second substrate 2, and the pixel driving circuit 10 is disposed on a side of the first buffer layer 14 away from the second substrate 2.

The pixel driving circuit 10 includes a semiconductor layer 101, a first gate insulating layer 102, a first gate layer 103, a second gate insulating layer 104, a second gate layer 105, an interlayer dielectric layer 106, and the source and drain metal layer 107. The semiconductor layer 101 is disposed on the side of the first buffer layer 14 away from the second substrate 2 and includes a channel region 1011 and a source region 1012 and a drain region 1013 located on opposite sides of the channel region 1011; the first gate insulating layer 102 covers the semiconductor layer 101 and the first buffer layer 14; the first gate layer 103 is disposed on the first gate insulating layer 102; the second gate insulating layer 104 covers the first gate layer 103 and the first gate insulating layer 102; the second gate layer 105 is disposed on the second gate insulating layer 104; the interlayer dielectric layer 106 covers the second gate layer 105 and the second gate insulating layer 104; the source and drain metal layer 107 is disposed on the interlayer dielectric layer 106.

Further, in order to reduce impedance, the source and drain metal layer 107 can be designed with a double-layered source and drain metal layer. The source and drain metal layer 107 includes a first source and drain metal layer 1071 and a second source and drain metal layer 1072 that are electrically connected. An insulating layer 108 is provided between the first source and drain metal layer 1071 and the second source and drain metal layer 1072. The first source and drain metal layer 1071 includes a source electrode 1071a, a drain electrode 1071b, and the data line 1071c. The pixel driving circuit 10 further includes a first via hole 109a and a second via hole 109b each extending through the first gate insulating layer 102, the second gate insulating layer 104, and the interlayer dielectric layer 106. The source electrode 1071a is electrically connected to the source electrode region 1012 through the first via hole 109a, and the drain electrode 1071b is electrically connected to the drain region 1013 through the second via 109b.

It can be understood that the conductive hole 12 extends through at least the interlayer dielectric layer 106, the first gate insulating layer 102, the second gate insulating layer 104, and the first buffer layer 14. In the embodiment of the present application, the conductive adhesive 121 is filled in the conductive hole 12 so that the data line 1071c is in contact with the conductive adhesive 121, and the conductive adhesive 121 is directly connected to the contact terminal 203. In this application, the first source and drain metal layer 1071 is not filled in the conductive hole 12, which can prevent the necessity for the data line 1071c crossing the interlayer dielectric layer 106, the first gate insulating layer 102, the second gate insulating layer 104, and the first buffer layer 14 when the data line 1071c is directly connected to the contact terminal 203, thereby preventing the problem of the data line 1071c from being broken or poorly connected in the conductive hole 12, so that the data line 1071c is in good contact with the contact terminal 203, which achieves corresponding functions.

Further, the second substrate 2 further includes a second base 21 and a second buffer layer 22. The bonding conductive layer 20 is disposed on a side of the second base 21 close to the first substrate 1, and the second buffer layer 22 covers the second substrate 21 and the bonding conductive layer 20. The conductive hole 12 extends from the first substrate 1 to the second substrate 2 and penetrates the second buffer layer 22.

Specifically, the second substrate 2 may be a glass substrate.

Specifically, the pixel unit 11 further includes a first pin 111 and a second pin 112 arranged on the side of the pixel driving circuit 10 away from the first substrate 13, the first pin 111 and the second pin 112 are bonded to the source and drain metal layer 107 by die bonding, and a packaging layer covers the LED chip 110 for packaging the LED chip 110.

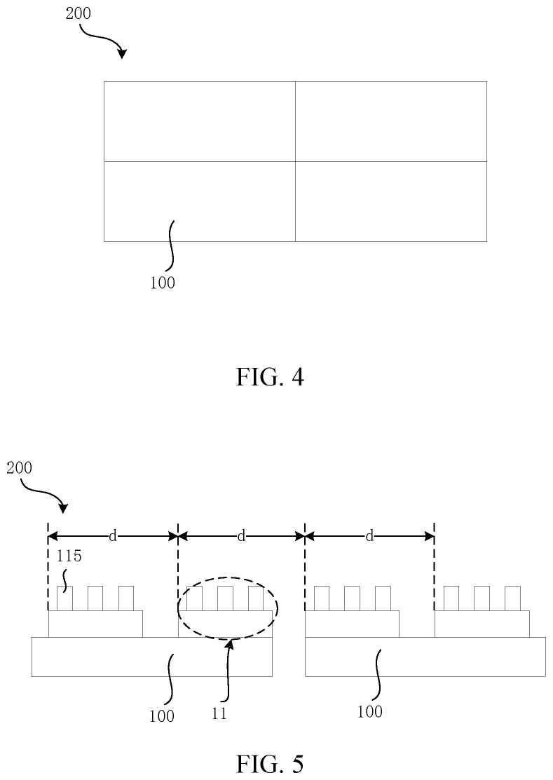

Please refer to FIG. 4 and FIG. 5. FIG. 4 is a schematic structural plan of a splicing screen provided by an embodiment of the present application. FIG. 5 is a schematic cross-sectional view of the splicing screen of FIG. 4.

An embodiment of the present application further provides a splicing screen 200, including a plurality of the display panels 100 spliced together. Each of the pixel units has a same size, which is d. It can be understood that, because the pixel driving circuit 10 disposed on the first substrate 1 and the bonding conductive layer 20 disposed on the second substrate 2 are electrically connected through the conductive holes 12 in the display panel 100, the lower frame of the display panel 100 is completely eliminated, which is beneficial to reduce seams of the splicing screen and reduce the probability of black lines at the junction; further, the display panel 100 can be a micro LED display panel or a mini LED display panel, which can solve a problem of package boundaries; further, disposing the gate driving circuit 15 in the display area of the first substrate 1 can completely eliminate the left and right borders of the display panel 100, so that the splicing screen 200 can be seamlessly spliced.

The present application has advantageous effects as follows: in the display panel and the splicing screen provided by the embodiments of the present application, based on the second substrate added to one side of the first substrate, the bonding conductive layer located on the lower frame of the first substrate as used in the prior art is transferred to the second substrate, and at least one conductive hole is located in the vacant area of the pixel unit of the first substrate, so that the pixel driving circuit disposed on the first substrate is electrically connected to the bonding conductive layer through the conductive hole, thereby achieving signal transmission across the substrates; since the first substrate does not need to leave space for arranging the bonding conductive layer, the lower frame of the first substrate can be completely eliminated, which is beneficial to achieve a full screen. In addition, the LED chip provided in the pixel unit has a self-encapsulation feature, which makes the area of the vacant area large enough to effectively prevent the formation of the conductive hole by mechanical processing from causing cracks to extend to the light-emitting area.

Accordingly, although the present invention has been disclosed as a preferred embodiment, it is not intended to limit the present invention. Those skilled in the art without departing from the scope of the present invention may make various changes or modifications, and thus the scope of the present invention should be after the appended claims and their equivalents.

What is claimed is:

1. A display panel, comprising:
a first substrate on which a plurality of pixel units are disposed, each of the pixel units comprising a light-emitting area and a vacant area, wherein a light-emitting diode (LED) chip and a pixel driving circuit for driving the LED chip to emit light are disposed in the light-emitting area, the vacant area is an area where the pixel driving circuit and the LED chip are not provided, at least a conductive hole is located in the vacant area of at least some of the pixel units, and the conductive hole is filled with a conductive adhesive; and
a second substrate disposed on a side of the first substrate facing away from the pixel units, wherein an orthographic projection of the second substrate on the first substrate is located in the first substrate, a bonding conductive layer is disposed on the second substrate, and the pixel driving circuit is electrically connected to the bonding conductive layer through the conductive hole.

2. The display panel of claim 1, wherein the first substrate further comprises a plurality of contact terminals disposed corresponding to the conductive holes, and one end of each of the contact terminals is electrically connected to the pixel driving circuit; and
the bonding conductive layer comprises a plurality of bonding terminals and a plurality of bonding traces, one end of each of the bonding traces is electrically connected to a corresponding one of the bonding terminals, and the other end of the bonding trace is electrically connected to the other end of the contact terminal through the conductive hole.

3. The display panel of claim 2, wherein the bonding traces comprise a plurality of fan-out traces, the pixel driving circuit comprises a source and drain metal layer, and the source and drain metal layer comprises a plurality of data lines, wherein each of the data lines is electrically connected to a corresponding one of the fan-out traces through the conductive hole.

4. The display panel of claim 2, wherein the bonding traces comprise a plurality of clock signal lines, the first substrate further comprises a gate driving circuit, and the gate driving circuit is electrically connected to the clock signal lines through the conductive holes.

5. The display panel of claim 4, wherein the gate driving circuit comprises a plurality of cascaded circuit units, and each of the circuit units is located in the vacant area.

6. The display panel of claim 2, wherein the first substrate comprises a first side and a second side that are oppositely disposed, and all the conductive holes are arranged close to the first side.

7. A display panel, comprising:
a first substrate on which a plurality of pixel units are disposed, each of the pixel units comprising a light-emitting area and a vacant area, wherein a light-emitting diode (LED) chip and a pixel driving circuit for driving the LED chip to emit light are disposed in the light-emitting area, the vacant area is an area where the pixel driving circuit and the LED chip are not provided, and at least a conductive hole is located in the vacant area of at least some of the pixel units; and
a second substrate disposed on a side of the first substrate facing away from the pixel units, wherein a bonding conductive layer is disposed on the second substrate, and the pixel driving circuit is electrically connected to the bonding conductive layer through the conductive hole.

8. The display panel of claim 7, wherein the first substrate further comprises a plurality of contact terminals disposed corresponding to the conductive holes, and one end of each of the contact terminals is electrically connected to the pixel driving circuit; and
the bonding conductive layer comprises a plurality of bonding terminals and a plurality of bonding traces, one end of each of the bonding traces is electrically connected to a corresponding one of the bonding terminals, and the other end of the bonding trace is electrically connected to the other end of the contact terminal through the conductive hole.

9. The display panel of claim 8, wherein the bonding traces comprise a plurality of fan-out traces, the pixel driving circuit comprises a source and drain metal layer, and the source and drain metal layer comprises a plurality of data lines, wherein each of the data lines is electrically connected to a corresponding one of the fan-out traces through the conductive hole.

10. The display panel of claim 8, wherein the bonding traces comprise a plurality of clock signal lines, the first substrate further comprises a gate driving circuit, and the gate driving circuit is electrically connected to the clock signal lines through the conductive holes.

11. The display panel of claim 10, wherein the gate driving circuit comprises a plurality of cascaded circuit units, and each of the circuit units is located in the vacant area.

12. The display panel of claim 8, wherein the first substrate comprises a first side and a second side that are oppositely disposed, and all the conductive holes are arranged close to the first side.

13. The display panel of claim 8, wherein the first substrate comprises a first side and a second side that are oppositely disposed, some of the conductive holes are located close to the first side, and some of the conductive holes are located close to the second side.

14. The display panel of claim 13, wherein the second substrate comprises a first fan-out area and a second fan-out area, an orthographic projection of the first fan-out area on the first substrate is close to the first side, and an orthographic projection of the second fan-out area on the first substrate is close to the second side; and
a driving chip is further provided on the second substrate, electrically connected to the bonding terminals, and disposed between the first fan-out area and the second fan-out area.

15. The display panel of claim 8, wherein number of the conductive holes is greater than or equal to number of the bonding traces.

16. The display panel of claim 7, wherein an orthographic projection of the second substrate on the first substrate is located in the first substrate.

17. The display panel of claim 7, wherein the conductive hole is filled with a conductive adhesive.

18. The display panel of claim 7, wherein the first substrate further comprises a first base and a first buffer layer, the first buffer layer disposed on a side of the first base away from the second substrate, and the pixel driving circuit arranged on a side of the first buffer layer away from the second substrate;
wherein the pixel driving circuit comprises:
a semiconductor layer disposed on the side of the first buffer layer away from the second substrate;
a first gate insulating layer covering the semiconductor layer and the first buffer layer;
a first gate layer disposed on the first gate insulating layer;
a second gate insulating layer covering the first gate layer and the first gate insulating layer;
a second gate layer disposed on the second gate insulating layer;
an interlayer dielectric layer covering the second gate layer and the second gate insulating layer; and
a source and drain metal layer arranged on the interlayer dielectric layer;
wherein the conductive hole penetrates the interlayer dielectric layer, the first gate insulating layer, the second gate insulating layer, and the first buffer layer.

19. The display panel of claim 18, wherein the second substrate further comprises:
a second base, wherein the bonding conductive layer is disposed on a side of the second base close to the first substrate; and
a second buffer layer covering the second base and the bonding conductive layer, the conductive hole extends from the first substrate to the second substrate and penetrates the second buffer layer.

20. A splicing screen, comprising a plurality of spliced display panels, wherein each of the display panel comprises:
a first substrate on which a plurality of pixel units are disposed, each of the pixel units comprising a light-emitting area and a vacant area, wherein a light-emitting diode (LED) chip and a pixel driving circuit for driving the LED chip to emit light are disposed in the light-emitting area, the vacant area is an area where the pixel driving circuit and the LED chip are not provided, and at least a conductive hole is located in the vacant area of at least some of the pixel units; and
a second substrate disposed on a side of the first substrate facing away from the pixel units, wherein a bonding conductive layer is disposed on the second substrate, and the pixel driving circuit is electrically connected to the bonding conductive layer through the conductive hole.
